(19) United States
(12) Patent Application Publication
(10) Pub. No.: US 2020/0181799 A1
(43) Pub. Date: Jun. 11, 2020

(54) Method for Preparing GaN Substrate Material

(71) Applicant: NANJING UNIVERSITY, Nanjing (CN)

(72) Inventors: Xiangqian XIU, Nanjing (CN); Yuewen LI, Nanjing (CN); Zening XIONG, Nanjing (CN); Rong ZHANG, Nanjing (CN); Xuemei HUA, Nanjing (CN); Zi-li XIE, Nanjing (CN); Peng CHEN, Nanjing (CN); Ping HAN, Nanjing (CN); Hai LU, Nanjing (CN); Yi SHI, Nanjing (CN); Youliao ZHENG, Nanjing (CN)

(73) Assignee: NANJING UNIVERSITY, Nanjing (CN)

(21) Appl. No.: 16/637,772

(22) PCT Filed: Aug. 8, 2018
(86) PCT No.: PCT/CN2018/099440

§ 371 Date: Feb. 10, 2020

(30) Foreign Application Priority Data
Aug. 14, 2017 (CN) 201710691185.9

(51) Int. Cl. C30B 25/18; C30B 29/40; C30B 29/16; C30B 33/08

(52) U.S. Cl. CPC C30B 25/183; C30B 33/08; C30B 29/16; C30B 29/406

(57) ABSTRACT

A method for preparing a GaN substrate material includes: performing in-situ epitaxy on a Ga₂O₃ thin film and a GaN thin film in a multifunctional HVPE growth system. First, the Ga₂O₃ thin film is grown on a substrate such as sapphire by an HVPE-like method, and the Ga₂O₃ is nitrided in an ammonia gas atmosphere to form a GaN/Ga₂O₃ composite thin film. Then, a GaN thick film is grown on the GaN/Ga₂O₃ composite thin film by HVPE to obtain a high-quality GaN thick film material. The Ga₂O₃ layer is removed by chemical etching to obtain a self-supporting GaN substrate material. Or, the conventional laser lift-off method is used to separate the GaN thick film from the heterogeneous substrate such as the sapphire to obtain a GaN self-supporting substrate material.

### CROSS REFERENCE TO THE RELATED APPLICATIONS

This application is the national phase entry of International Application No. PCT/CN2018/099440, filed on Aug. 8, 2018, which is based upon and claims priority to Chinese Patent Application No. 201710691185.9, filed on Aug. 14, 2017, the entire contents of which are incorporated herein by reference.

### TECHNICAL FIELD

The present disclosure relates to a method and process for obtaining a GaN substrate material by first performing an in-situ epitaxy on a gallium oxide film through halide vapor phase epitaxy (HVPE), then performing a nitridation to form a GaN/Ga₂O₃ composite structure, and next performing an in-situ epitaxy on a GaN thick film, followed by a chemical etching or laser lift-off.

### BACKGROUND

Group III-V nitride materials (also known as GaN-based materials), mainly including GaN, InGaN, and AlGaN alloy materials, are novel semiconductor materials that have received much worldwide attention in recent years. GaN-based materials are direct wide-band-gap semiconductor materials with superior performance such as a continuously variable direct band gap between 1.9 eV and 6.2 eV, an excellent physical and chemical stability, a highly saturated electron drift velocity, a high breakdown field strength, a high thermal conductivity, etc. GaN-based materials are widely applied in preparing short-wavelength semiconductor optoelectronic devices, high-frequency microelectronic devices, high-voltage microelectronic devices, high-temperature microelectronic devices and the like, for example, the GaN-based materials are used for manufacturing blue/purple/ultraviolet light-emitting devices, blue/purple/ultraviolet light-detecting devices, high-temperature high-power devices, high-frequency high-power devices, high-field high-power devices, field emission devices, radiation-resistant devices, piezoelectric devices, etc.

There are numerous methods for the growth of GaN-based materials, such as metal-organic chemical vapor deposition (MOCVD), high-temperature high-pressure growth of GaN bulk single crystals, molecular beam epitaxy (MBE), sublimation method, HVPE, etc. Due to the limitations caused by the physical properties of GaN-based materials, the growth of GaN bulk single crystals encounters severe difficulties, and thus has not yet been put into practical use. Because of the high growth rate and lateral-longitudinal epitaxy ratio, the HVPE can be used for homoepitaxial growth of self-supporting GaN substrates, which has attracted wide attention and research. The HVPE has an outstanding advantage, i.e., making GaN grow at an extremely high growth rate, generally up to tens to thousands of microns/hour. The dislocation density in the epitaxial layer is 1-2 orders of magnitude lower than that obtained by other methods. Generally, the dislocation density of the epitaxial layer obtained directly by HVPE is about 10⁸ cm⁻². Further research can better reduce the dislocation density in the epitaxial layer. Currently, the HVPE is mainly used to directly grow GaN-based materials on a sapphire substrate, and then a separation is performed to obtain a GaN substrate material.

Gallium oxide (Ga₂O₃) is a wide-bandgap semiconductor with the energy gap (Eg) equal to 4.9 eV, and its electrical conductivity and light emission property have been attracting attention for a long time. Ga₂O₃ is a transparent oxide semiconductor material, which has broad application prospects in optoelectronic devices and is particularly used as an insulating layer for Ga-based semiconductor materials and as an ultraviolet filter. The Ga₂O₃ single crystal can be used as a GaN-based substrate material because the Ga₂O₃ single crystal is able to transmit blue light and ultraviolet light. Optical Wavelength Laboratories, Inc (OWL) and Waseda University jointly developed a conductive Ga₂O₃ single crystal in 2005 with a resistivity of 0.02 Q·cm. Multilayer gallium nitride series compounds are grown on a Ga₂O₃ substrate by the MOCVD method to obtain a vertically emitting blue light-emitting diode.

The Ga₂O₃ single crystal is generally prepared by chemical vapor deposition (CVD), hydrothermal method, etc., and can also be obtained by epitaxy using methods similar to HVPE. Gallium nitride can be obtained by replacing the ammonia gas used in the growth of GaN by HVPE with oxygen gas and controlling process parameters including temperature, flow rate and pressure. The present disclosure provides a method and a process for obtaining a self-supporting GaN substrate by first using HVPE to perform an in-situ epitaxy on a gallium oxide film, and then performing the in-situ epitaxy on a GaN film after nitriding.

Lattice mismatch and thermal mismatch may cause relatively large stress in the GaN epitaxial layer because the existing GaN substrates are generally grown on heterogeneous substrates such as sapphire. After removing the heterogeneous substrates whether by mechanical polishing or laser lift-off, the stress still exists in the GaN-based material, resulting in a performance drop of GaN-based materials and devices.

### SUMMARY

The objective of the present invention is as follows. Since Ga₂O₃ single crystal is capable of transmitting blue light and ultraviolet light, the Ga₂O₃ single crystal can be used as a GaN substrate material. Moreover, when Ga₂O₃ is used as a substrate, the Ga₂O₃ in an interface layer can be removed by a chemical etching method to obtain a self-supporting GaN substrate after the GaN thick film is grown to obtain a self-supporting GaN substrate. The present disclosure provides a method for obtaining a high-quality low-stress self-supporting GaN substrate material by first performing an epitaxy on a gallium oxide film through HVPE, then performing an in-situ nitridation to form a GaN/Ga₂O₃ composite structure, and further performing the in-situ epitaxy on a GaN thick film through the HVPE.

The technical solution of the present invention is as follows. A method for preparing a GaN substrate material includes: performing in-situ epitaxy on a Ga₂O₃ thin film and a GaN thin film in a multifunctional HVPE growth system. First, the Ga₂O₃ thin film is grown on a substrate such as sapphire or a silicon wafer by an HVPE-like method, and the Ga₂O₃ is nitrided in an ammonia gas atmosphere to form a GaN/Ga₂O₃ composite thin film. Then, a GaN thick film is grown on the GaN/Ga₂O₃ composite thin film by HVPE to obtain a high-quality GaN thick film material. The Ga₂O₃ in the interface layer is removed by chemical etching to obtain a self-supporting GaN substrate material. Or, a conventional laser lift-off is used to separate the GaN thick film from the heterogeneous substrate such as the sapphire to obtain the GaN self-supporting substrate material.

Growing the Ga₂O₃ thin film by HVPE requires the following conditions. Oxygen gas and hydrogen chloride or chlorine gas are used as reactant gases. Hydrogen chloride or chlorine gas reacts with gallium to form gallium chloride as a gallium source. Under specific temperature and specific process conditions, oxygen gas reacts with gallium chloride to generate gallium oxide. The pressure is equal to one bar pressure and the temperature is 900-1150° C. The ratio of input 0 atoms to input Ga atoms is 1.5-15.

In the method for annealing and nitriding the gallium oxide obtained by the in-situ epitaxy by the HVPE in the ammonia gas atmosphere or ammonia-nitrogen mixed gas, gallium oxide can be nitrided into a GaN single crystal layer by controlling process parameters (such as ammonia gas flow rate, nitrogen gas flow, temperature, time, etc.). Annealing is performed under a specific atmosphere, a specific temperature and a specific time, the gallium oxide is entirely nitrided to form a GaN thin film buffer layer or a seed layer. Or, annealing is performed in a specific atmosphere, a specific temperature, and a specific time, the gallium oxide is partially nitrided to form a GaN/Ga₂O₃ composite substrate as a buffer layer or a seed layer. Annealing is performed at a temperature of 800-1100° C. for 0.5-5 hours with the ammonia gas flow rate of 100-5000 sccm.

In the process of the HVPE growth, the GaN thick film is continuously in-situ grown on the GaN/Ga₂O₃ composite thin film by HVPE.

The advantages of the present invention are as follows. There is provided a process and technique for obtaining a self-supporting GaN substrate by first performing an in-situ epitaxy on gallium oxide in an HVPE growth system and carrying out a nitridation to form a GaN seed layer or buffer layer, and then continuously growing a GaN thick film by in-situ epitaxy. Compared with GaN, Ga₂O₃ is more conducive to the release of material stress and lift-off of the material. The nitride formed by nitriding the Ga₂O₃ thin film can be used as a homoepitaxial layer of the GaN. The quality of GaN crystal can be improved and stress therein can be lowered during the epitaxial regrowth of the GaN. Moreover, it can further prevent oxygen gas from diffusing into the GaN during the subsequent HVPE, thus not reducing the material quality. Due to the weak connection between Ga₂O₃ and the gallium nitride layer formed after nitriding, the stress is relatively low. When growing a GaN thick film on the composite thin film substrate, the stress in the GaN thick film material grown by HVPE and the dislocation density can be effectively reduced. Therefore a high-quality self-supporting GaN thick film can be obtained, and meanwhile, the separation is easy.

### BRIEF DESCRIPTION OF THE DRAWINGS

FIG. 1 is a schematic diagram showing the reaction principle of growing gallium oxide/gallium nitride by HVPE.

FIG. 2 is a flowchart of the technical route according to the present invention.

FIG. 3 is a scanning electron microscope (SEM) image showing the surface morphology of the GaN single crystal layer/Ga₂O₃ composite thin film formed by nitriding according to embodiment 1.

FIG. 4 is a diagram of the GaN substrate material obtained by growing a GaN thick film on the GaN/Ga₂O₃ composite thin film substrate by HVPE and etching according to embodiment 1.

### DETAILED DESCRIPTION OF THE EMBODIMENTS

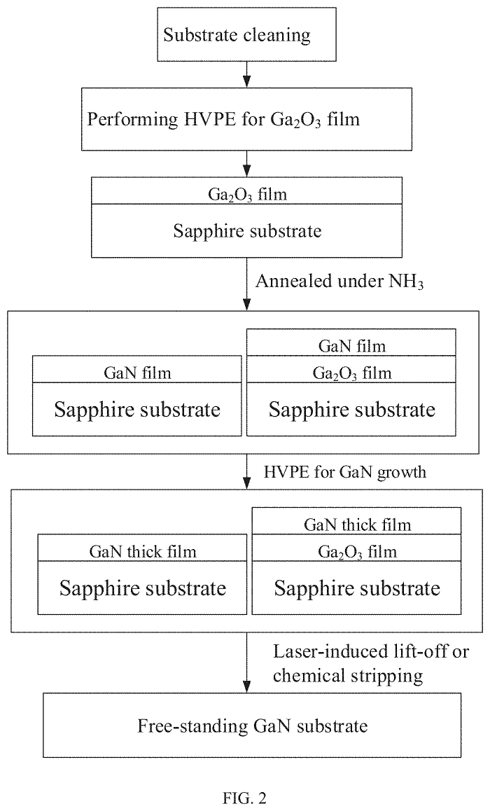

The method and process of the present invention include the following parts: preparing a gallium oxide film by an HVPE method; forming a GaN/Ga₂O₃ composite thin film by nitriding the gallium oxide film; and performing an in-situ epitaxy to obtain a GaN thick film by HVPE. The specific flowchart of technical route is shown in FIG. 2.

On the GaN/Ga₂O₃ composite structure film, in-situ growth of a GaN thick film is continued by HVPE.

In an HVPE growth system, oxygen gas is newly introduced as a source gas. Ga₂O₃ is performed with an in-situ epitaxy by a method similar to the HVPE growth of the GaN. First, the Ga₂O₃ thin film is grown on a substrate such as sapphire by HVPE, and then Ga₂O₃ is partially or entirely nitrided in an ammonia gas atmosphere to form a GaN/Ga₂O₃ composite thin film. Then, a GaN thick film is grown on the buffer layer by HVPE to obtain a high-quality GaN thick film material. The Ga₂O₃ in the interface layer is removed by chemical etching to obtain a self-supporting GaN substrate material. Or, a conventional laser lift-off method is used to separate the GaN thick film from the heterogeneous substrate such as the sapphire to obtain a GaN self-supporting substrate material.

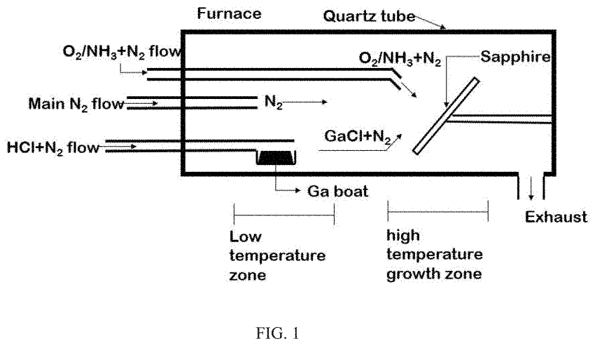

A method for preparing a gallium oxide thin film by an HVPE method is provided, where the reaction system mainly includes two temperature regions. In the low-temperature region, the temperature is generally 850-950° C., and gallium reacts with hydrogen chloride or chlorine gas to generate GaCl as a gallium source. Oxygen gas is used as an oxygen source, GaCl and O₂ are mixed and reacted in a high-temperature growth region to obtain the gallium oxide thin film (as shown in FIG. 1). The temperature in the high-temperature region is generally 900-1150° C. The reaction is carried out under normal pressure. The ratio of input O atoms to input Ga atoms is 1.5-15.

A method for forming a GaN/Ga₂O₃ composite thin film by nitriding a gallium oxide thin film is provided. In the HVPE growth system, after gallium oxide is grown, oxygen gas is stopped. After a period, the GaN/Ga₂O₃ composite film can be obtained by introducing ammonia gas and annealing at a specific temperature for a certain time. The ammonia gas flow rate is 100-5000 sccm, the temperature is 800-1100° C., and the annealing time is 0.5-5 hours.

After completing the nitriding, the oxygen gas is stopped. After a period, ammonia gas is introduced and maintained at a certain flow rate, and hydrogen chloride gas is introduced to react with gallium to generate GaCl. The growth of GaN is performed on the above GaN/Ga₂O₃ composite film by HVPE to obtain a GaN thick film material with a thickness of generally greater than 10 microns.

The self-supporting GaN substrate material can be obtained by removing the gallium oxide in the interface layer through chemical etching, or by separating the GaN thick film from the heterogeneous substrate through the traditional laser lift-off method.

According to one of the implementation modes of the present invention, the preparation of the gallium nitride substrate material includes the following steps.

1. A substrate (sapphire) is cleaned and processed.

2. A gallium oxide thin film is prepared by an HVPE method. In the low-temperature region, the temperature is generally 850-950° C. Gallium reacts with hydrogen chloride or chlorine gas to generate GaCl as a gallium source. Oxygen gas is used as an oxygen source, GaCl and O₂ are mixed and reacted in a high-temperature growth region to obtain the gallium oxide thin film. The temperature in the high-temperature region is generally 900-1150° C. The reaction is carried out under normal pressure. The ratio of input oxygen gas to input Ga atoms is 1.5-15.

3. After the gallium oxide thin film is grown, the oxygen gas is stopped. After a period, ammonia gas is introduced, and a high-temperature annealing treatment is performed. Parameters: the temperature is 800-1100° C., the time is 0.5-5 hours; the gas atmosphere is ammonia gas or ammonia-nitrogen mixed gas, and the ammonia gas flow rate is 100-5000 sccm.

4. After completing the annealing and nitridation, GaN thick film is grown by HVPE by adjusting parameters such as temperature and gas flow rate.

5. The sample obtained in step 4 is cooled and taken out, and then placed in an acid solution or alkali solution. The oxide in the interface layer is etched to obtain the self-supporting GaN substrate material. The acid can be 30-50% hydrogen fluoride (HF) aqueous solution.

6. The sample obtained in step 4 is cooled and taken out. The conventional laser lift-off method is used to separate the GaN thick film from the heterogeneous substrate to obtain the GaN self-supporting substrate material.

### Embodiment 1

A method for preparing a GaN substrate material includes the following steps.

1. A sapphire substrate is cleaned and processed by conventional methods.

2. A gallium oxide thin film is prepared by an HVPE method. In the low-temperature region, the temperature is set to be 850° C. Gallium reacts with hydrogen chloride to generate GaCl as a gallium source. Oxygen gas is used as an oxygen source, GaCl and O₂ are mixed and reacted in a high-temperature growth region to obtain the gallium oxide thin film. The temperature in the high-temperature region is set to be 950° C. The reaction is carried out under normal pressure. The ratio of input oxygen gas to input Ga is 3.

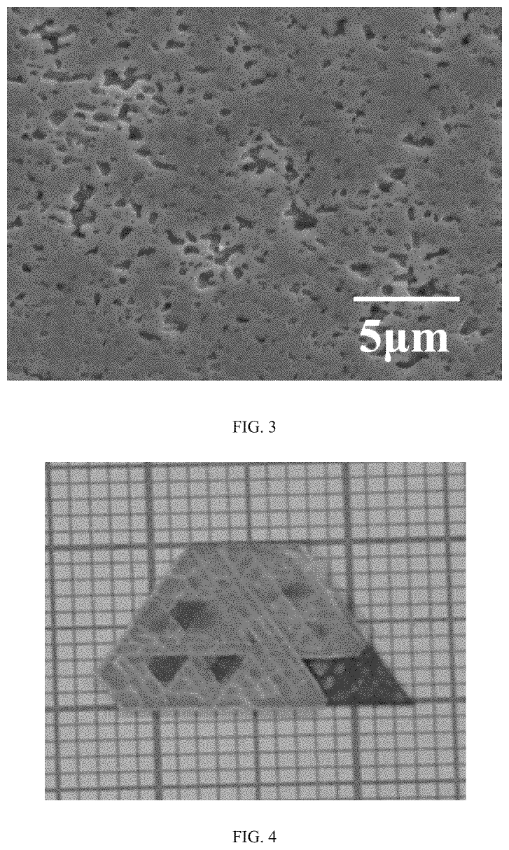

3. After the gallium oxide thin film is grown, the oxygen gas is stopped. After a period, ammonia gas is introduced, and a high-temperature annealing treatment is performed to obtain a GaN/Ga₂O₃ composite structure. Parameters: the temperature is 800° C., the time is 5 hours; the gas atmosphere is ammonia gas, and the ammonia gas flow rate is 200 sccm. The surface SEM diagram of the obtained GaN/Ga₂O₃ composite substrate is shown in FIG. 3.

4. After completing the annealing and nitridation, GaN thick film is grown by HVPE after adjusting the temperature in the low-temperature region to be 850° C., the temperature in the high-temperature to be 1050° C., ammonia gas flow rate to be 500 sccm, flow rate of nitrogen gas carried by ammonia gas to be 5 slm, hydrogen chloride flow rate to be 50 sccm, flow rate of nitrogen gas carried by hydrogen chloride to be 500 sccm, and total nitrogen gas flow rate to be 10 sccm.

5. The sample obtained in step 4 is cooled and taken out, and then placed in an acid solution. The oxide in the interface layer is etched to obtain a self-supporting GaN substrate material. The acid solution is a 40% HF aqueous solution. The separated self-supporting GaN substrate material is shown in FIG. 4. In FIG. 4, the white part is sapphire, and the black part is gallium nitride. To illustrate the separation effect, sapphire is only partially stripped.

### Embodiment 2

A method for preparing of a GaN substrate material includes the following steps.

1. A sapphire substrate is cleaned and processed by conventional methods.

2. A gallium oxide thin film is prepared by an HVPE method. In the low-temperature region, the temperature is set to be 870° C. Gallium reacts with chlorine gas to generate GaCl as a gallium source. Oxygen gas is used as an oxygen source, GaCl and O₂ are mixed and reacted in a high-temperature growth region to obtain the gallium oxide thin film. The temperature in the high-temperature region is set to be 900° C. The reaction is carried out under normal pressure. The ratio of input oxygen gas to input Ga is 1.5.

3. After the gallium oxide thin film is grown, the oxygen gas is stopped. After a period, ammonia gas is introduced, and a high-temperature annealing treatment is performed to obtain a GaN/Ga₂O₃ composite thin film. Parameters: the temperature is 900° C., the time is 4 hours; the gas atmosphere is ammonia-nitrogen mixed gas, and the total flow rate is 5000 sccm. In this embodiment, the flow ratio of ammonia gas to nitrogen gas is 1:4.

4. After completing the annealing and nitridation, GaN thick film is grown by HVPE after adjusting parameters including temperature and gas flow rate.

5. The sample obtained in step 4 is cooled and taken out, and then placed in a sodium hydroxide or potassium hydroxide alkali solution. The oxide in the interface layer is etched to obtain a self-supporting GaN substrate material.

### Embodiment 3

A method for preparing of a GaN substrate material includes the following steps.

1. A substrate (sapphire) is cleaned and processed.

2. A gallium oxide thin film is prepared by an HVPE method. In the low-temperature region, the temperature is set to be 950° C. Gallium reacts with hydrogen chloride or chlorine gas to generate GaCl as a gallium source. Oxygen gas is used as an oxygen source, GaCl and O₂ are mixed and reacted in a high-temperature growth region to obtain the gallium oxide thin film. The temperature in the high-temperature region is 1150° C. The reaction is carried out under normal pressure. The ratio of input oxygen gas to input Ga is 15.

3. After the gallium oxide thin film is grown, the oxygen gas is stopped. After a period, ammonia gas is introduced, and a high-temperature annealing treatment is performed to form a GaN/Ga₂O₃ composite thin film. Parameters: the temperature is 1100° C., the time is 1 hour; the gas atmosphere is ammonia gas, and the ammonia gas flow rate is 100 sccm.

4. After completing the annealing and nitridation, GaN thick film is grown by HVPE after adjusting the parameters such as temperature and gas flow rate.

5. The sample obtained in step 4 is cooled and taken out. The conventional laser lift-off method is used to separate the GaN thick film from the heterogeneous substrate to obtain a GaN self-supporting substrate material.

It should be understood by those of ordinary skill in the art that the above description is only specific embodiments of the present invention and is not intended to limit the present invention. Any modification, equivalent replacement, or improvement made within the spirit and principle of the present invention shall fall in the protection scope of the present invention.

What is claimed is:

1. A method for preparing a GaN substrate material, wherein an in-situ epitaxy is performed on a Ga₂O₃ thin film and a GaN thin film in a multifunctional halide vapor phase epitaxy (HVPE) growth system, comprising:
firstly, growing the Ga₂O₃ thin film on a substrate by a halide vapor phase epitaxy (HVPE) method, and performing a nitridation on a surface of the Ga₂O₃ thin film in an ammonia gas atmosphere or ammonia-nitrogen mixed gas to form a GaN/Ga₂O₃ composite thin film;
then, growing a GaN thick film by the HVPE method on the GaN/Ga₂O₃ composite thin film to obtain a high-quality GaN thick film material; and
removing the Ga₂O₃ in an interface layer of the GaN/Ga₂O₃ composite thin film by a chemical etching to obtain a self-supporting GaN substrate material; or, separating the GaN thick film from the substrate by a laser lift-off method to obtain the self-supporting GaN substrate material; wherein
growing the Ga₂O₃ thin film by the HVPE method requires the following conditions: oxygen gas and hydrogen chloride or chlorine gas are used as reactant gases, the hydrogen chloride or the chlorine gas reacts with gallium to form gallium chloride as a gallium source, the oxygen gas reacts with the gallium chloride to generate gallium oxide on the substrate at a pressure equal to one bar pressure and a first predetermined temperature of is 900-1150° C., and a ratio of input O atoms to input Ga atoms is (1.5−15):1.

2. The method for preparing the GaN substrate material according to claim 1, wherein, an annealing is performed at a second predetermined temperature of 800-1100° C. and under ammonia gas atmosphere or ammonia-nitrogen mixed gas for 0.5-5 hours, a surface of the gallium oxide is nitrided to form the GaN/Ga₂O₃ composite thin film for a next epitaxy, an ammonia gas flow rate is 100-5000 sccm, and a flow ratio of ammonia gas to nitrogen gas in the ammonia-nitrogen mixed gas is (0.5−5):1.

3. The method for preparing the GaN substrate material according to claim 2, wherein, the GaN thick film is continuously in-situ grown on the GaN/Ga₂O₃ composite film by the HVPE method.
